(19) United States
(12) Patent Application Publication
(10) Pub. No.: US 2009/0218662 A1
(43) Pub. Date: Sep. 3, 2009

(54) SEMICONDUCTOR DEVICE

(76) Inventors: Shinji Kudoh, Saitama (JP); Ryu Hirata, Saitama (JP); Shinichi Miyazono, Saitama (JP)

Correspondence Address: WILMERHALE/DC, 1875 PENNSYLVANIA AVE., NW, WASHINGTON, DC, 20006, US

(21) Appl. No.: 12/394,862

(22) Filed: Feb. 27, 2009

(30) Foreign Application Priority Data
Feb. 29, 2008 (JP) U.M.2008-001148

(51) Int. Cl. H01L 29/861; H01L 29/06

(52) U.S. Cl. 257/653; 257/E29.005; 257/E29.327

(57) ABSTRACT

A semiconductor device includes: a first semiconductor region of a first conductive type; a second semiconductor region of the first conductive type formed on an upper surface of the first semiconductor region and having a lower impurity concentration than that of the first semiconductor region; a third semiconductor region of the first conductive type formed on the upper surface of the first semiconductor region and having a higher impurity concentration than that of the second semiconductor region; and a fourth semiconductor region of a second conductive type different from the first conductive type formed on upper surfaces of the second semiconductor region and the third semiconductor region. A PN junction is formed between the second semiconductor region and third semiconductor region and the fourth semiconductor region. The second semiconductor region is formed to surround the third semiconductor region.

### CROSS-REFERENCE TO RELATED APPLICATIONS

This application is based upon and claims priority from Japanese Utility Model Application No. 2008-1148 filed on Feb. 29, 2008, the entire contents of which are incorporated herein by reference.

### BACKGROUND OF THE INVENTION

1. Technical Field

The present invention relates to a semiconductor device capable of reducing a forward voltage.

2. Description of the Related Art

JP-A-2005-317894 describes a semiconductor device. An example of the semiconductor device is shown in FIG. 2. As shown in FIG. 2, the semiconductor device includes a first semiconductor region 7 serving as a cathode region, a second semiconductor region 8, and a third semiconductor region 9 serving as an anode region. The third semiconductor region 9 includes an outer edge region that extends downward so as to surround an outer side surface of the second semiconductor region 8 and an outer side surface of the first semiconductor region 7. The third semiconductor region 9 is formed by diffusing impurities. Therefore, an impurity diffusion concentration decreases toward downward (deeper side), and an electrical resistance increases more greatly in a path provided in outer side of the outer edge region (i.e., toward a side surface side of a semiconductor substrate). A PN junction region between the second semiconductor region 8 and the third semiconductor region 9 is formed by adjacent regions having relatively higher impurity concentrations, as compared with a PN junction region between the first semiconductor region 7 and the third semiconductor region 9.

The PN junction region between the second semiconductor region 8 and the third semiconductor region 9 is formed on an inside of a device which is surrounded by the outer edge region (a center side of the semiconductor substrate), and is disposed entirely spaced from the side surface of the semiconductor substrate. Consequently, when a backward bias is applied to a portion between the anode and cathode regions, a reverse current flows to the PN junction region between the second semiconductor region 8 and the third semiconductor region 9, and a current hardly flows to the side surface side of the semiconductor substrate so that a backward withstanding voltage does not fluctuate.

However, the above-described semiconductor device includes a semiconductor layer having a comparatively high resistance (the first semiconductor region 7) and provided under an active region including the PN junction region formed between the second semiconductor region 8 and the third semiconductor region 9, which may increase a forward voltage. Moreover, the PN junction formed between the first semiconductor region 7 and the third semiconductor region 9 is exposed at the side surface of the semiconductor substrate, and the exposed surface is subjected to wafer dicing, which may increase a leakage current.

### BRIEF SUMMARY OF THE INVENTION

The present invention was made in consideration of the above circumstances, and an object thereof is to provide a semiconductor device with a low forward voltage.

According to an aspect of the invention, there is provided a semiconductor device comprising: a first semiconductor region of a first conductive type; a second semiconductor region of the first conductive type formed on an upper surface of the first semiconductor region and having a lower impurity concentration than that of the first semiconductor region; a third semiconductor region of the first conductive type formed on the upper surface of the first semiconductor region and having a higher impurity concentration than that of the second semiconductor region; and a fourth semiconductor region of a second conductive type different from the first conductive type formed on upper surfaces of the second semiconductor region and the third semiconductor region. A PN junction is formed between the second semiconductor region and third semiconductor region and the fourth semiconductor region. The second semiconductor region is formed to surround the third semiconductor region.

### BRIEF DESCRIPTION OF THE DRAWING

FIG. 1 is a cross-sectional view showing a semiconductor device according to an embodiment of the present invention; and

FIG. 2 is a cross-sectional view showing a related-art semiconductor device.

### DETAILED DESCRIPTION OF THE EMBODIMENT

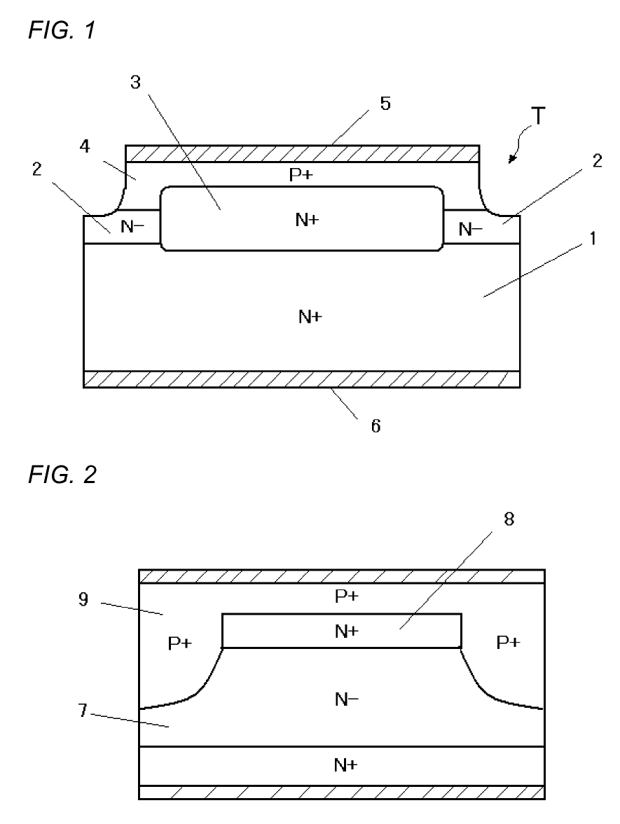

A semiconductor device according to an embodiment of the present invention is described with reference to FIG. 1. As shown in FIG. 1, each of the semiconductor device and semiconductor regions includes vertically opposing major surfaces (upper and lower surfaces). Herein, the upper major surface thereof is referred to as a first major surface, and the lower major surface thereof is referred to as a second major surface.

As shown in FIG. 1, a semiconductor device according to an embodiment of the present invention includes a first semiconductor region 1 of an N⁺ semiconductor region having a relatively high impurity concentration. The first semiconductor region 1 is formed by diffusing an N-type impurity from the second major surface (a lower surface) of a wafer. A second semiconductor region 2 is formed on the first major surface side of the first semiconductor region 1, and has an impurity concentration lower than that of the first semiconductor region 1.

The N-type impurity is partially diffused into the second semiconductor region 2 to form a third semiconductor region 3 in the second semiconductor region 2. Accordingly, the third semiconductor region 3 has a higher impurity concentration as compared with the second semiconductor region 2. The third semiconductor region 3 is not formed in the entire second semiconductor region 2 but in only a center side portion of a semiconductor substrate of the second semiconductor region 2. For this reason, the second semiconductor region 2 is left on an outer peripheral side of the semiconductor substrate, and the third semiconductor region 3 is annularly surrounded by the second semiconductor region 2 in plan view (as viewed from a direction perpendicular to the major surface).

A P-type impurity is diffused into the first major surface of each of the second semiconductor region 2 and the third semiconductor region 3 entirely so as to form a fourth semiconductor region 4. In this case, the fourth semiconductor region is formed relatively shallowly on the third semiconductor region 3 having a relatively high impurity concentration and is formed relatively deeply on the second semiconductor region 2 having a relatively low impurity concentration, which corresponds to a difference in the concentration between the second semiconductor region 2 and the third semiconductor region 3 (the impurity concentration of the third semiconductor region 3 is higher than that of the second semiconductor region 2).

Consequently, a PN junction between the second semiconductor region 2 and the fourth semiconductor region 4 is formed in a position spaced from the first major surface of the semiconductor substrate as compared with a PN junction between the third semiconductor region 3 and the fourth semiconductor region 4. The PN junction between the third semiconductor region 3 and the fourth semiconductor region 4 is formed between adjacent regions having relatively high impurity concentrations as compared with the PN junction between the second semiconductor region 2 and the fourth semiconductor region 4. Consequently, when a backward voltage to be applied to the two PN junctions is raised, a breakdown is generated between the third semiconductor region 3 and the fourth semiconductor region 4.

The PN junction between the third semiconductor region 3 and the fourth semiconductor region 4 is annularly surrounded by the fourth semiconductor region 4 and is not exposed to a side surface of the semiconductor substrate. Accordingly, a backward withstanding voltage can be prevented from fluctuating, and an increase in a leakage current can also be suppressed effectively. Even if a backward bias is applied to the PN junction formed between the third semiconductor region 3 and the fourth semiconductor region 4 so that a depletion layer is extended, a increase in a reverse current can also be suppressed because a distance from the PN junction to an upper end of the fourth semiconductor region 4 is ensured.

A mesa trench T is formed on a side surface of the semiconductor substrate by an etching processing as shown. The mesa trench T is formed from the first major surface (upper surface) of the semiconductor substrate toward the second major surface (lower surface), and a bottom surface of the mesa trench T is positioned closer to the second major surface than the PN junction formed between the second semiconductor region 2 and the fourth semiconductor region 4. For this reason, the PN junction between the second semiconductor region 2 and the fourth semiconductor region 4 is exposed on a side surface of the mesa trench T. Since the side surface of the mesa trench T is subjected to the etching processing, the side surface of the mesa trench T has a comparatively excellent crystallinity with a less broken layer. A vertical cut side surface is formed between the mesa trench T and the second major surface of the semiconductor substrate. The side surface is formed by wafer dicing. For this reason, the crystallinity is poorer as compared with the side surface of the mesa trench T. In the semiconductor device of FIG. 1, the PN junction is not exposed from the side surface having the poor crystallinity. The mesa trench T is formed to annularly surround the fourth semiconductor region 4.

A first electrode portion 5 is formed on the first major surface of the fourth semiconductor region 4. A second electrode portion 6 is formed on the second major surface of the first semiconductor region 1. The mesa trench T is formed by: partially etching the first electrode portion 5 to form an opening; and etching the fourth semiconductor region 4 and the third semiconductor region 3 by using the first electrode portion 5 (with the opening) as a mask. The first electrode portion 5 and the second electrode portion 6 constitute an anode electrode and a cathode electrode, respectively.

The invention is not limited to the embodiment but various changes can be made. For example, even if each semiconductor region is formed of a reversed conductive type, the same advantages can be produced.

According to the embodiment of the invention, no high resistance layer is provided under an active region, while maintaining a structure in which a breakdown region is formed on a center side of a semiconductor substrate and a fluctuation in a backward voltage is prevented well. Moreover, a PN junction portion is not subject to dicing but a chemical treatment (an etching treatment), thereby preventing a crystalline distortion of a semiconductor crystal located on an exposed surface of the PN junction which increases a leakage current.

In other words, the embodiment overcomes a disadvantage of an increase of the forward voltage. Further, a large leakage current is prevented by preventing a distortion of a crystal because the exposed surface of the PN junction portion is not subjected to dicing but the chemical treatment. Accordingly, the semiconductor device according to the embodiment of the invention can implement a low forward voltage and a low leakage current at the same time.

Further, the high resistance layer is not present under the active region. Therefore, it is hard for a specific resistance of a wafer to influence various characteristics of a semiconductor device. Even if a foreign substance adheres to the exposed portion of the PN junction portion, a fluctuation in the backward withstanding voltage is caused with difficulty. Thus, the invention can contribute to an enhancement in a reliability of the semiconductor device.

What is claimed is:

1. A semiconductor device comprising:
a first semiconductor region of a first conductive type;
a second semiconductor region of the first conductive type formed on an upper surface of the first semiconductor region and having a lower impurity concentration than that of the first semiconductor region;
a third semiconductor region of the first conductive type formed on the upper surface of the first semiconductor region and having a higher impurity concentration than that of the second semiconductor region; and
a fourth semiconductor region of a second conductive type different from the first conductive type formed on upper surfaces of the second semiconductor region and the third semiconductor region,
wherein a PN junction is formed between the second semiconductor region and third semiconductor region and the fourth semiconductor region, and
wherein the second semiconductor region is formed to surround the third semiconductor region.

2. The semiconductor device according to claim 1, wherein a mesa trench is formed at side surfaces of the second semiconductor region and the fourth semiconductor region, so as to expose the PN junction formed between the second semiconductor region and the fourth semiconductor region is exposed at a side surface of the mesa trench.

3. The semiconductor device according to claim 2, wherein the fourth semiconductor region is formed relatively deeply on a mesa trench side than on a side apart from the mesa trench.
